(19) United States
(12) Patent Application Publication
(10) Pub. No.: US 2022/0208698 A1
(43) Pub. Date: Jun. 30, 2022

(54) SEMICONDUCTOR DEVICE AND METHOD FOR MAKING THE SAME

(71) Applicant: Pure Metallica Co., Ltd., Taipei City (TW)

(72) Inventors: Chao-Cheng TING, Hsinchu City (TW); Yu-Hsien LIN, Kaohsiung City (TW); Yu-An LI, New Taipei Cirty (TW)

(21) Appl. No.: 17/646,126

(22) Filed: Dec. 27, 2021

Related U.S. Application Data
(60) Provisional application No. 63/131,030, filed on Dec. 28, 2020.

(51) Int. Cl. H01L 23/60; H01L 23/367; H01L 23/535

(52) U.S. Cl. CPC H01L 23/60; H01L 23/535; H01L 23/367

(57) ABSTRACT

A semiconductor device includes: a chip unit, a conductive wire unit, and a cover unit. The chip unit includes a substrate formed with an interconnect structure, and a semiconductor chip disposed on the substrate. The conductive wire unit includes a conductive wire that interconnects the semiconductor chip and the interconnect structure. The cover unit includes a cover member that covers the conductive wire. The cover member includes an insulating layer formed by atomic layer deposition. A method for making the semiconductor device is also disclosed.

### CROSS-REFERENCE TO RELATED APPLICATION

This application claims the benefit of U.S. Provisional Patent Application 63/131,030, filed on Dec. 28, 2020, which is incorporated by reference herein in its entirety.

### FIELD

The disclosure relates to a semiconductor device and a method for making the same.

### BACKGROUND

Wire bonding technology involves formation of conductive wires (e.g., gold wires, copper wires, etc.) on a semiconductor chip for electrical connection of the semiconductor chip to an external electronic element. Wire bonding is widely applied in packaging of a semiconductor device. The use of spray coating for covering the conductive wires with a functional layer is common so as to improve properties of the conductive wires.

The functional layer may be an insulating layer, a heat dissipating layer made of, e.g., aluminum nitride (AlN), an electromagnetic shielding layer made of a material different from that of the conductive wires, or an anti-oxidation layer.

However, the conductive wires might easily collapse due to insufficient mechanical strength during spray coating process. Furthermore, in a subsequent packaging procedure, the conductive wires might be in contact with each other due to displacement thereof, which causes short circuit. Thus, electrical failure might occur in a semiconductor device thus prepared, resulting in a poor yield of the semiconductor device.

### SUMMARY

Therefore, an object of the disclosure is to provide a semiconductor device that can alleviate or eliminate at least one of the drawbacks of the prior art. A second object of the disclosure is to provide a method for making the semiconductor device.

According to a first aspect of the disclosure, the semiconductor device includes: a chip unit, a conductive wire unit, and a cover unit. The chip unit includes a substrate formed with an interconnect structure, and a semiconductor chip disposed on the substrate. The conductive wire unit includes a conductive wire that interconnects the semiconductor chip and the interconnect structure. The cover unit includes a cover member that covers the conductive wire. The cover member has a thickness that ranges from one hundredth to one tenth of a diameter of the conductive wire. The cover member includes an insulating layer that is formed by atomic layer deposition.

According to a second aspect of the disclosure, a method for making the aforesaid semiconductor device includes: forming the semiconductor chip on the substrate; electrically connecting the semiconductor chip to the interconnect structure of the substrate through the conductive wire; and forming the insulating layer that covers the conductive wire by atomic layer deposition.

### BRIEF DESCRIPTION OF THE DRAWINGS

Other features and advantages of the disclosure will become apparent in the following detailed description of the embodiment(s) with reference to the accompanying drawings, of which:

FIG. 1 is a schematic view of an embodiment of a semiconductor device in accordance with the present disclosure;

FIG. 2 is a flow diagram illustrating a method for making the embodiment of the semiconductor device in accordance with the present disclosure;

FIG. 3 is a fragmentary cross-sectional view showing a conductive wire and a cover unit included in the embodiment of the semiconductor device in accordance with the present disclosure; and

FIG. 4 is a fragmentary cross-sectional view showing a variation of the cover unit covering the conductive wire of the embodiment of the semiconductor device in accordance with the present disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

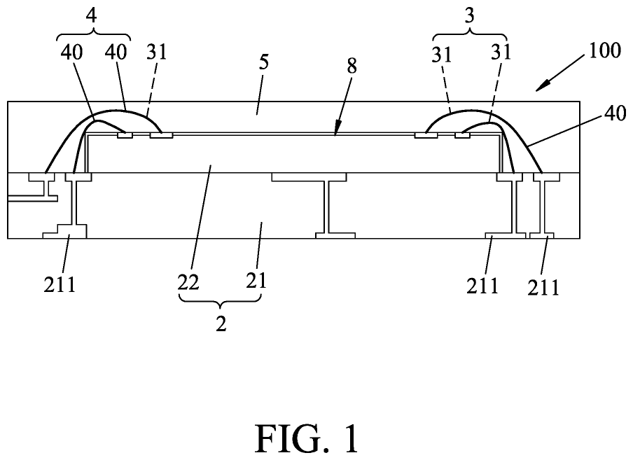

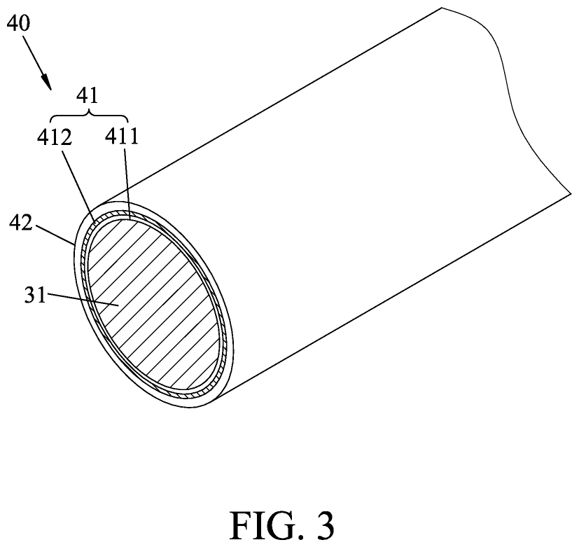

Referring to FIGS. 1 and 3, an embodiment of a semiconductor device 100 according to the disclosure includes a chip unit 2, a conductive wire unit 3, a cover unit 4, and an encapsulating layer 5.

The chip unit 2 includes a substrate 21 and a semiconductor chip 22 that is disposed on the substrate 21. The substrate 21 may be a silicon substrate, a sapphire substrate, a quartz substrate, or a circuit board. In this embodiment, the substrate 21 is formed with an interconnect structure 211 that is electrically connected to the semiconductor chip 22.

The semiconductor chip 22 may be a semiconductor component with desired function. In this embodiment, the chip unit 2 includes one of the semiconductor chip 22. Nevertheless, in some embodiments, the chip unit 2 may include a plurality of the semiconductor chips 22 with the same or different functions. The semiconductor chips 22 may be arranged in a matrix or stacked on one another, and are disposed on the substrate 21 to be electrically connected to the interconnect structure 211.

The conductive wire unit 3 includes at least one conductive wire 31 that interconnects the semiconductor chip 22 and the interconnect structure 211 of the substrate 21. To be specific, two ends of the conductive wire 31 are respectively connected to the semiconductor chip 22 and the interconnect structure 211 of the substrate 21. The conductive wire 31 may be made of a material, such as copper (Cu), aluminum (Al), or gold (Au). In this embodiment, the conductive wire unit 3 includes a plurality of the conductive wires 31.

The cover unit 4 includes a cover member 40 that covers the conductive wire 31. The cover member 40 may have a thickness which is measured from an outer surface of the conductive wire 31 and which ranges from the one hundredth to one tenth of a diameter of the conductive wire 31. In certain embodiments, the cover member 40 includes a functional layer 41 and an insulating layer 42 that are arranged in an order from a surface of the conductive wire 31. The functional layer 41 is disposed between the conductive wire 31 and the insulating layer 42. The functional layer 41 may be completely covered by the insulating layer 42. In certain embodiments, in which the conductive wire unit 3 includes a plurality of the conductive wires 31, the cover unit 4 includes a plurality of the cover members 40 each covering a respective one of conductive wires 31.

The functional layer 41 may be made of a desired material based on actual requirements, and is formed by adequate techniques, e.g., spray coating or deposition, in accordance with the characteristics of the desired material. In certain embodiments, the functional layer 41 is formed by atomic layer deposition (ALD), and have a thickness not greater than 1 μm. In certain embodiments, the functional layer 41 may be made of a heat dissipating material or an electromagnetic shielding material. Examples of the heat dissipating material may include aluminum nitride (AlN), a two-dimensional material having thermal conductive property, and molybdenum disulfide. Examples of the electromagnetic shielding material includes copper, aluminum, a two-dimensional material having electromagnetic shielding property, molybdenum disulfide, and tungsten diselenide. The two-dimensional material for each of the heat dissipating material and the electromagnetic shielding material may be a carbon-based two-dimensional material, e.g., graphene.

In certain embodiments, the functional layer 41 may include a plurality of sub-layers, and each of the sub-layers is made of the aforesaid heat dissipating material or the aforesaid electromagnetic shielding material. In this embodiment, the functional layer 41 includes a first sub-layer 411 which functions as a heat dissipating layer and which is made of AlN, and a second sub-layer 412 which functions as an electromagnetic shielding layer and which is made of aluminum.

The insulating layer 42 may be made of any suitable insulating material, and may be formed by, e.g., atomic layer deposition (ALD). Examples of the insulating material includes aluminum oxide, silicon dioxide, titanium dioxide, silicon oxynitride, magnesium oxide, and zinc oxide. Due to the characteristics of ALD, atoms of the insulating layer are densely and regularly arranged, and the insulating layer 42 may be controlled to have a relatively small thickness. In certain embodiments, the insulating layer 42 has a thickness that is not greater than 1 μm. In certain embodiments, the thickness of the insulating layer 42 may be not greater than 0.5 μm. In this embodiment, the insulating layer 42 is made of aluminum oxide, and has the thickness about 0.5 μm.

It is noted that the functional layer 41 of the cover member 40 may be a single layer, e.g., only the heat dissipating layer 411 or only the electromagnetic shielding layer 412. In certain embodiments, the functional layer 41 may be dispensed with, and the cover member 40 only includes the insulating layer 42. By forming the insulating layer 42 that covers the conductive wire 31, although the conductive wires 31 are in contact with each other due to displacement during the packaging process, short circuit can be avoided.

In certain embodiments, in which the cover member includes the functional layer 41 and the insulating layer 42, the thickness of the insulating layer 42 ranges from one thousandth to five hundredth of the thickness of the cover member 40.

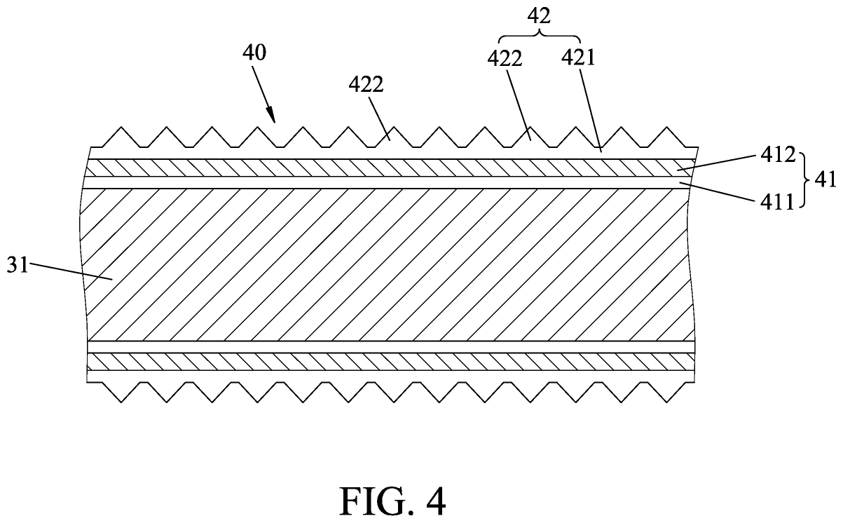

The insulating layer 42 may, as shown in FIG. 3, have a substantially even and smooth surface. However, in certain embodiments, the insulating layer 42 of the cover member 40 may have a different surface structure based on actual requirements. As shown in FIG. 4, in some embodiments, the insulating layer 42 has a main body 421 and a roughened structure 422 formed on the main body 421. With the roughened structure 422, the surface area of the insulating layer 42 may be increased, so that adhesion between the insulating layer 42 and the encapsulating layer 5 can be improved.

The roughened structure 422 is a micro-structure which increases roughness of the surface of the insulating layer 42. In certain embodiments, the roughened structure 422 may include a plurality of protrusions that are regularly or irregularly distributed on the main body 421 of the insulating layer 42. The shape of the roughened structure 422 may vary, and may be, e.g., a cone shape, a truncated cone shape, etc.

The encapsulating layer 5 covers the semiconductor chip 22, the conductive wire unit 3, and the cover unit 4. The encapsulating layer 5 is used for protecting the semiconductor chip 22 and the conductive wire unit 3 from physical or chemical damages, and may be made of, but not limited to, a polymer material, e.g., epoxy resin, polyimide, or silicon resin.

In this embodiment, as shown in FIG. 1, the semiconductor device 100 further includes a covering layer 8 that covers the semiconductor chip 22 of the chip unit 2. The covering layer 8 is therefore sandwiched between the semiconductor chip 22 and the encapsulating layer 5. A portion of the semiconductor chip 22 not covered by the covering layer 8 is electrically connected to the conductive wire 31. The covering layer 8 and the cover member 40 are made of the same material.

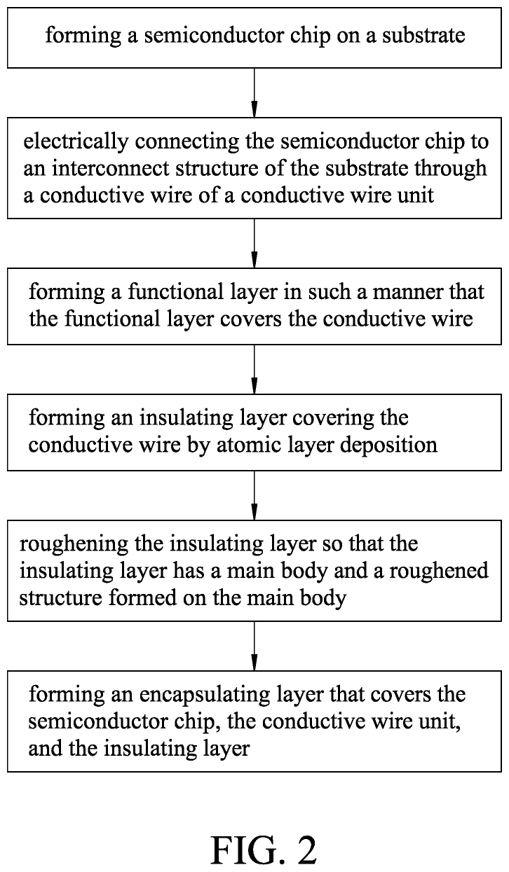

Referring to FIGS. 1 and 2, a method for making the aforesaid semiconductor device 100 includes:

forming the semiconductor chip 22 on the substrate 21;

electrically connecting the semiconductor chip 22 to the interconnect structure 211 of the substrate 21 through the conductive wire 21;

forming the functional layer 41 in such a manner that the functional layer 41 covers the conductive wire 31;

forming the insulating layer 42 that covers the functional layer 41 and the conductive wire 31 by atomic layer deposition; and

forming the encapsulating layer 5 that covers the semiconductor chip 22, the conductive wire unit 3, and the insulating layer 42.

The semiconductor chip 22 and the substrate 21 are cooperatively formed into the chip unit 2. The chip unit 2 may be covered by a protecting layer (not shown) which protects the semiconductor chip 22 from being damaged in the subsequent manufacturing steps. The functional layer 41 may be formed by spray coating or deposition technique. In this embodiment, the functional layer 41 is formed by atomic layer deposition (ALD). As mentioned above, the functional layer 41 may be formed to include sub-layers, e.g., the first and second sub-layers 411, 412, which may, as mentioned above, function as the heat dissipating layer and the electromagnetic shielding layer, respectively, and which are made of, e.g., aluminum nitride (AlN) and aluminum, respectively. Since relevant experimental factors and materials for forming the heat dissipating layer and the electromagnetic shielding layer by atomic layer deposition are known to the person skilled in the art, detailed descriptions are omitted herein for the sake of brevity.

It should be noted that, in certain embodiments, the functional layer 41 may be formed as a single layer or may be dispensed with (i.e., the step of forming the functional layer 41 may be omitted).

The insulating layer 42 is formed on the functional layer 41 by ALD so as to obtain a semi-product. The thickness of the insulating layer 42 is not greater than 1 μm.

In certain embodiments, the step of forming the functional layer 41 and the step of forming the insulating layer 42 are performed by ALD. The ALD is a layer-by-layer film deposition technique conducted in a vapor phase environment. In the ALD process, due to small external force, a film formed thereby may be relatively thin and even. Thus, the thicknesses of the insulating layer 42 and the functional layer 41 may be controlled to be in nanoscale or atomic level. The functional layer 41 and the insulating layer 42, which constitute the cover unit 4, may be densely formed and completely cover the conductive wire 31, while the thicknesses thereof are controlled to be relatively thin so as to prevent the conductive wire 31 from collapse caused by excessive thickness of the insulating layer or the functional layer 41. It should be noted that, the functional layer 41 and the insulating layer 42 may also be deposited on the chip unit 2 to cover the semiconductor chip 22 so as to form the covering layer 8. In other words, the covering layer 8 and the cover unit 4 are simultaneously formed by, e.g., ALD.

The atomic layer deposition involves the following steps: placing the chip unit 2 and the conductive wire unit 3 in a chamber (not shown); injecting a precursor gas into the chamber; allowing the precursor to react with and bond to surfaces of the chip unit 2 and the conductive wire unit 3 until the precursor completely covers the conductive wire 31; injecting an inert gas into the chamber to expel unreacted precursor; and injecting a reactant gas into the chamber and allowing the reactant to react with the precursor so as to form the dense cover unit 4 which covers the conductive wire 31. In this embodiment, the insulating layer 42 is made of aluminum oxide, and the precursor, the inert gas and the reactant are respectively trimethylalane (TMA, Al₂(CH₃)₆), nitrogen gas, and water vapor.

Since relevant experimental factors and materials for ALD are known to the person skilled in the art, detailed descriptions are omitted herein for the sake of brevity.

In certain embodiments, the method may further include, after the step of forming the insulating layer 42 and before the step of forming the encapsulating layer 5, the step of roughening the insulating layer 42. In the roughening step, a surface of the insulating layer 42 is subjected to a deposition process or an etching technique, so that the insulating layer 42 is formed to have the main body 421 and the roughened structure 422 formed on the main body 421. As mentioned above, the roughened structure 422 may be made by partially etching the insulating layer 42 or by spray coating or deposition of the roughened structure 422.

In the step of forming the encapsulating layer 5, the semi-product is disposed in a mold (not shown), and an encapsulating material is then injected into the mold, followed by curing the encapsulating material.

In the aforesaid injection molding process, injection of the encapsulating material may easily cause displacement of the conductive wire 31 due to the conductive wires 31 being in contact with each other, thereby causing short circuit. However, since the conductive wire 31 is covered by the insulating layer 42, the short circuit problem may be eliminated.

In sum, in the present disclosure, use of ALD to form the cover unit 4 would prevent collapse of the conductive wire 31 during spray coating. Moreover, the functional layer 41 could provide desired properties to the conductive wire 31, and short circuit due to displacement of the conductive wires 31 can be avoided by having the insulating layer 42.

In the description above, for the purposes of explanation, numerous specific details have been set forth in order to provide a thorough understanding of the embodiments. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. A semiconductor device comprising:
a chip unit including a substrate that is formed with an interconnect structure, and a semiconductor chip that is disposed on the substrate;
a conductive wire unit including a conductive wire that interconnects said semiconductor chip and said interconnect structure; and
a cover unit including a cover member that covers said conductive wire, said cover member having a thickness that ranges from one hundredth to one tenth of a diameter of said conductive wire, said cover member including an insulating layer that is formed by atomic layer deposition and that has a thickness not greater than 1 μm.

2. The semiconductor device as claimed in claim 1, wherein said cover member further includes a functional layer that is disposed between said conductive wire and said insulating layer, and that is completely covered by said insulating layer.

3. The semiconductor device as claimed in claim 2, wherein the thickness of said insulating layer ranges from one thousandth to five hundredth of the thickness of said cover member.

4. The semiconductor device as claimed in claim 2, wherein said functional layer of said cover member is made of one of a heat dissipating material and an electromagnetic shielding material.

5. The semiconductor device as claimed in claim 4, wherein said heat dissipating material is selected from the group consisting of aluminum nitride, carbon-based two-dimensional material, molybdenum disulfide, and combinations thereof, and said electromagnetic shielding material is selected from the group consisting of copper, aluminum, carbon-based two-dimensional material, molybdenum disulfide, tungsten diselenide, and combinations thereof.

6. The semiconductor device as claimed in claim 2, wherein said functional layer of said cover member includes a plurality of sub-layers, each of said sub-layers being made of one of a heat dissipating material and an electromagnetic shielding material.

7. The semiconductor device as claimed in claim 6, wherein said heat dissipating material is selected from the group consisting of aluminum nitride, carbon-based two-dimensional material, molybdenum disulfide, and combinations thereof, and said electromagnetic shielding material is selected from the group consisting of copper, aluminum, carbon-based two-dimensional material, molybdenum disulfide, tungsten diselenide, and combinations thereof.

8. The semiconductor device as claimed in claim 1, further comprising an encapsulating layer that covers said semiconductor chip, said conductive wire unit, and said cover unit.

9. The semiconductor device as claimed in claim 1, wherein said insulating layer of said cover member is made of a material selected from the group consisting of aluminum oxide, silicon dioxide, titanium dioxide, silicon oxynitride, magnesium oxide, zinc oxide, and combinations thereof.

10. The semiconductor device as claimed in claim 1, wherein said insulating layer of said cover member has a main body and a roughened structure formed on said main body.

11. A method for making a semiconductor device as claimed in claim 1, wherein the method comprises:
forming the semiconductor chip on the substrate;
electrically connecting the semiconductor chip to the interconnect structure of the substrate through the conductive wire; and
forming the insulating layer that covers the conductive wire by atomic layer deposition.

12. The method as claimed in claim 11, further comprising, before the step of forming the insulating layer, forming a functional layer in such a manner that the functional layer covers the conductive wire, followed by forming the insulating layer that completely covers the functional layer.

13. The method as claimed in claim 12, wherein, in the step of forming the functional layer, the functional layer is made of one of a heat dissipating material and an electromagnetic shielding material.

14. The method as claimed in claim 13, wherein, in the step of forming the functional layer, said heat dissipating material is selected from the group consisting of aluminum nitride, carbon-based two-dimensional material, molybdenum disulfide, and combinations thereof, and said electromagnetic material is selected form the group consisting of copper, aluminum, carbon-based two-dimensional material, molybdenum disulfide, tungsten diselenide, and combinations thereof.

15. The method as claimed in claim 12, wherein, in the step of forming the functional layer, the functional layer is formed to include a plurality of sub-layers, each of the sub-layers being made of one of a heat dissipating material and an electromagnetic shielding material.

16. The method as claimed in claim 15, wherein, in the step of forming the functional layer, said heat dissipating material is selected from the group consisting of aluminum nitride, carbon-based two-dimensional material, molybdenum disulfide, and combinations thereof, and said electromagnetic shielding material is selected from the group consisting of copper, aluminum, carbon-based two-dimensional material, molybdenum disulfide, tungsten diselenide, and combinations thereof.

17. The method as claimed in claim 12, wherein the functional layer is formed by atomic layer deposition to have a thickness which is not greater than 1 μm.

18. The method as claimed in claim 12, further comprising, after the step of forming the insulating layer, forming an encapsulating layer that covers the semiconductor chip, the conductive wire unit, and the insulating layer.

19. The method as claimed in claim 11, further comprising, roughening the insulating layer so that the insulating layer has a main body and a roughened structure formed on the main body.
